(19) United States
(12) Patent Application Publication
(10) Pub. No.: US 2020/0205234 A1
(43) Pub. Date: Jun. 25, 2020

(54) APPARATUS AND METHOD FOR TREATING SUBSTRATE

(71) Applicant: SEMES CO., LTD., Chungcheongnam-do (KR)

(72) Inventors: Sung Yong LEE, Anyang-si (KR); Donghyuk SEO, Cheonan-si (KR)

(73) Assignee: SEMES CO., LTD.

(21) Appl. No.: 16/725,701

(22) Filed: Dec. 23, 2019

(30) Foreign Application Priority Data
Dec. 21, 2018 (KR) 10-2018-0167716

(51) Int. Cl. H05B 1/02; H01L 21/67

(52) U.S. Cl. CPC H05B 1/0233; H01L 21/67248

(57) ABSTRACT

Disclosed is a substrate treating apparatus that includes a housing having a process space therein, a plate that supports the substrate in the housing, a heating member that is provided in the plate and that heats the substrate, a power supply that supplies AC power to the heating member, and a controller that controls the heating member using the AC power output from the power supply, in which the controller controls heating temperature of the substrate by alternately turning on and off a control input for controlling the heating member.

### CROSS-REFERENCE TO RELATED APPLICATIONS

A claim for priority under 35 U.S.C. § 119 is made to Korean Patent Application No. 10-2018-0167716 filed on Dec. 21, 2018, in the Korean Intellectual Property Office, the entire contents of which are hereby incorporated by reference.

### BACKGROUND

Embodiments of the inventive concept described herein relate to an apparatus and method for treating a substrate, and more particularly, relate to a substrate treating apparatus and method for stably controlling the temperature of a substrate by adjusting a control input for controlling a heating member.

Various processes, such as photolithography, etching, deposition, ion implantation, cleaning, and the like, are performed to manufacture semiconductor elements. Among these processes, the photolithography process for forming a pattern plays an important role in achieving high density integration of the semiconductor elements.

The photolithography process includes a coating process, an exposing process, and a developing process, and a bake process is performed before and after the exposing process. The bake process is a process of performing heat treatment on a substrate. When the substrate is placed on a heating plate, the heat treatment is performed on the substrate through a heater provided in the heating plate.

In general, a zero-crossing output is used to control the heater, and the control output of the heater is generated during the time that the control input is turned on.

The heater control method in the related art has a problem in that it takes relatively much time to turn on or off the control output and therefore temperature vibration occurs in the heater. In addition, the heater control method has problems in that the time that it takes the heater to converge to a set temperature by the control output increases and the temperature control performance of the heater is deteriorated.

### SUMMARY

Embodiments of the inventive concept provide a substrate treating apparatus and method for preventing temperature vibration and improving the temperature control performance of a heater by adjusting a control input for controlling a heating member.

The technical problems to be solved by the inventive concept are not limited to the aforementioned problems, and any other technical problems not mentioned herein will be clearly understood from the following description by those skilled in the art to which the inventive concept pertains.

According to an exemplary embodiment, a substrate treating apparatus includes a housing having a process space therein, a plate that supports the substrate in the housing, a heating member that is provided in the plate and that heats the substrate, a power supply that supplies AC power to the heating member, and a controller that controls the heating member using the AC power output from the power supply, in which the controller controls heating temperature of the substrate by alternately turning on and off a control input for controlling the heating member.

The controller may determine turn-on time of the control input supplied to the heating member, based on a frequency of the AC power.

The controller may determine turn-on timing of the control input depending on an output ratio of the AC power and unit pulse time of the AC power.

The controller may calculate the unit pulse time of the AC power, based on the frequency of the AC power.

The controller may calculate a unit output of the AC power using the output ratio of the AC power and the unit pulse time of the AC power, and when the sum of the unit outputs is greater than or equal to the unit pulse time, the controller may determine a corresponding time point to be the turn-on timing of the control input.

The controller may repeatedly perform the process of determining the turn-on timing of the control input.

The controller may determine the turn-on timing of the control input in consideration of sampling time.

According to an exemplary embodiment, a bake apparatus includes a housing having a process space therein, a plate that supports a substrate in the housing, a heating member that is provided in the plate and that heats the substrate, a power supply that supplies AC power to the heating member, and a controller that controls the heating member using the AC power output from the power supply, in which the controller controls heating temperature of the substrate by alternately turning on and off a control input for controlling the heating member and determining turn-on timing of the control input depending on an output ratio of the AC power and unit pulse time of the AC power.

The controller may calculate the unit pulse time of the AC power, based on a frequency of the AC power.

The controller may calculate a unit output of the AC power using the output ratio of the AC power and the unit pulse time of the AC power, and when the sum of the unit outputs is greater than or equal to the unit pulse time, the controller may determine a corresponding time point to be the turn-on timing of the control input.

The controller may repeatedly perform the process of determining the turn-on timing.

The controller may determine the turn-on timing of the control input in consideration of sampling time.

According to an exemplary embodiment, a method for treating a substrate by controlling a heating member provided in a plate for supporting the substrate in a chamber includes controlling heating temperature of the substrate by alternately turning on and off a control input for controlling the heating member.

AC power may be supplied to the heating member, and turn-on time of the control input may be determined based on a frequency of the AC power.

Turn-on timing of the control input may be determined depending on an output ratio of the AC power and unit pulse time of the AC power.

The unit pulse time of the AC power may be calculated based on the frequency of the AC power.

A unit output of the AC power may be calculated by using the output ratio of the AC power and the unit pulse time of the AC power, and when the sum of the unit outputs is greater than or equal to the unit pulse time, a corresponding time point may be determined to be the turn-on timing of the control input.

The process of determining the turn-on timing of the control input may be repeatedly performed.

The turn-on timing of the control input may be determined in consideration of sampling time.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view of substrate treating equipment as viewed from above;

FIG. 2 is a view illustrating the substrate treating equipment of FIG. 1 when viewed in direction A-A;

FIG. 3 is a view illustrating the substrate treating equipment of FIG. 1 when viewed in direction B-B;

FIG. 4 is a view illustrating the substrate treating equipment of FIG. 1 when viewed in direction C-C;

FIG. 5 is a plan view illustrating a bake unit according to an embodiment of the inventive concept;

FIG. 6 is a sectional view illustrating a heating unit for performing a heating process according to an embodiment of the inventive concept;

FIGS. 7 and 8 are views illustrating waveforms of control inputs and control outputs according to an embodiment of the inventive concept; and

FIGS. 9 and 10 are flowcharts illustrating a substrate treating method according to an embodiment of the inventive concept.

### DETAILED DESCRIPTION

Hereinafter, embodiments of the inventive concept will be described in more detail with reference to the accompanying drawings. Various modifications and variations can be made to the embodiments of the inventive concept, and the scope of the inventive concept should not be construed as limited to the embodiments set forth herein. These embodiments are provided so that this disclosure will be thorough and complete, and will fully convey the scope of the inventive concept to those skilled in the art. Accordingly, in the drawings, the shapes of components are exaggerated for clarity of illustration.

Equipment according to this embodiment may be used to perform a photolithography process on a substrate such as a semiconductor wafer or a flat display panel. In particular, the equipment according to this embodiment may be connected to a stepper and may be used to perform a coating process and a developing process on a substrate. In the following description, it will be exemplified that a wafer is used as a substrate.

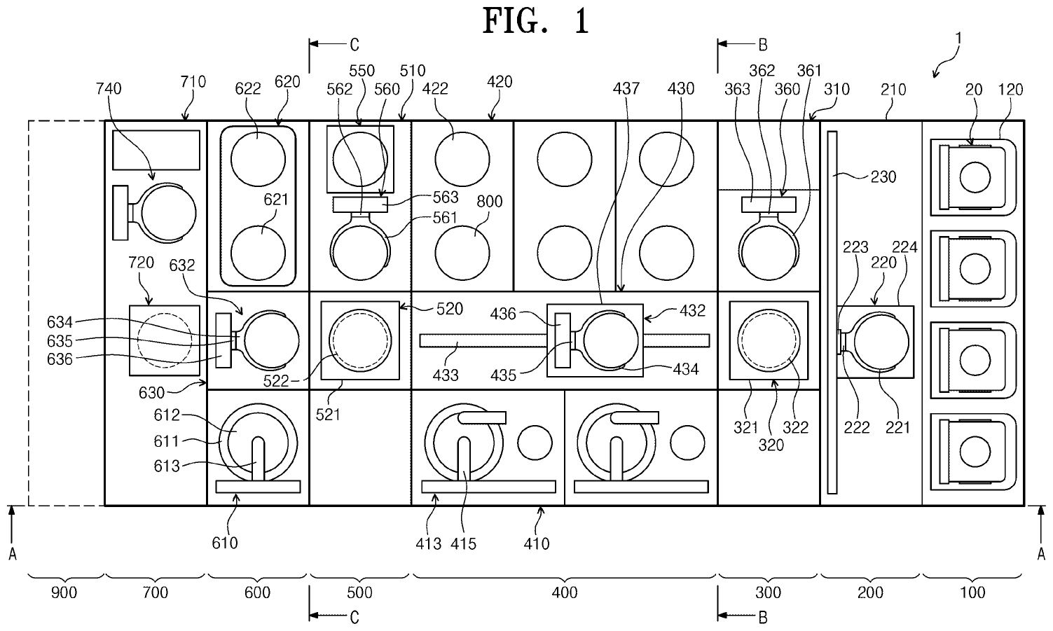

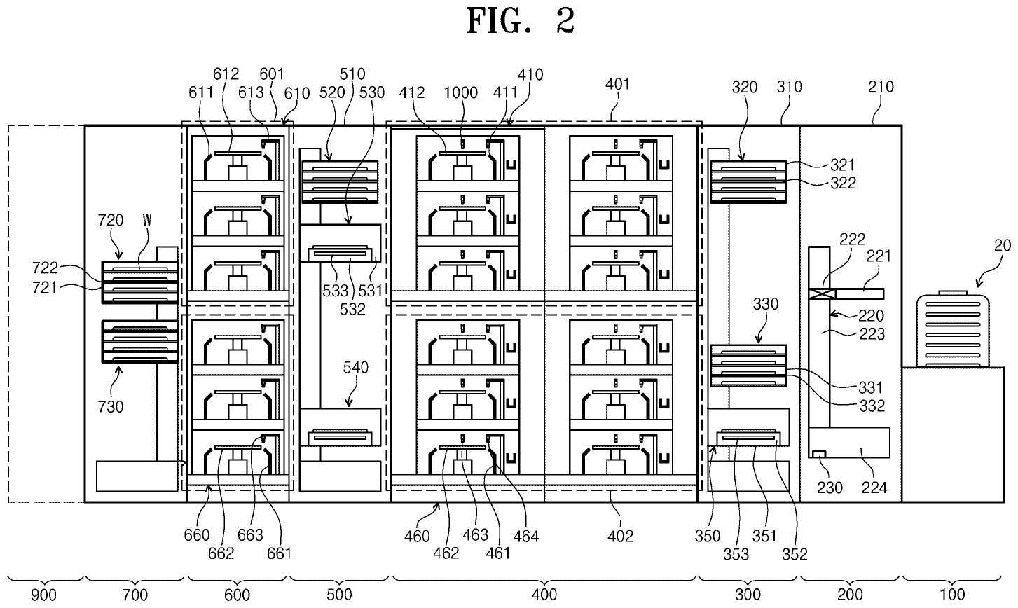

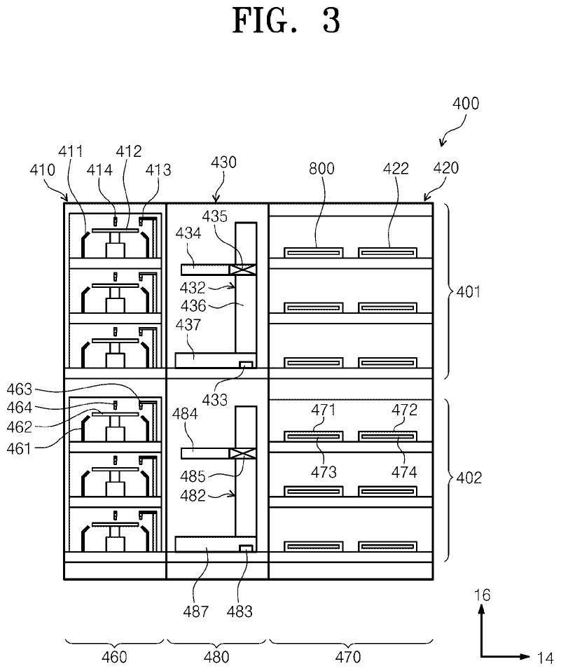

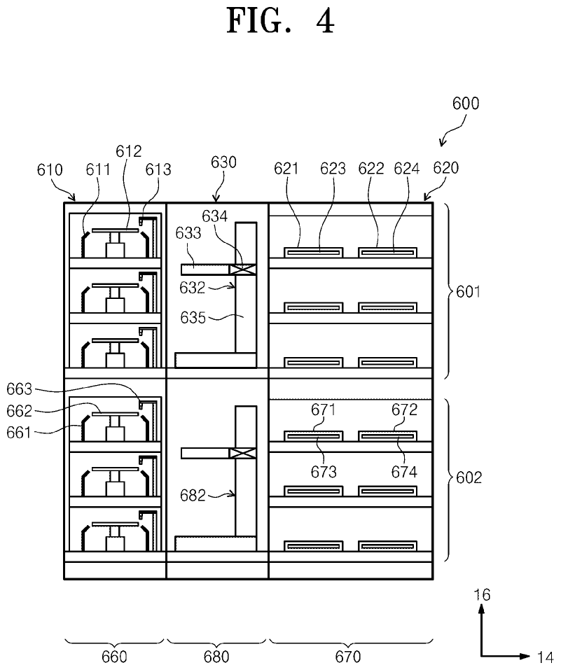

FIGS. 1 to 4 are schematic views illustrating substrate treating equipment according to an embodiment of the inventive concept.

Referring to FIGS. 1 to 4, the substrate treating equipment 1 includes a load port 100, an index module 200, a first buffer module 300, a coating and developing module 400, a second buffer module 500, a pre/post-exposure process module 600, and an interface module 700. The load port 100, the index module 200, the first buffer module 300, the coating and developing module 400, the second buffer module 500, the pre/post-exposure process module 600, and the interface module 700 are sequentially arranged in a row in one direction.

Hereinafter, the direction in which the load port 100, the index module 200, the first buffer module 300, the coating and developing module 400, the second buffer module 500, the pre/post-exposure process module 600, and the interface module 700 are arranged is referred to as a first direction 12. A direction perpendicular to the first direction 12 when viewed from above is referred to as a second direction 14, and a direction perpendicular to the first direction 12 and the second direction 14 is referred to as a third direction 16.

Substrates W are moved in a state of being received in cassettes 20. The cassettes 20 have a structure that can be sealed from the outside. For example, front open unified pods (FOUPs), each of which has a door at the front, may be used as the cassettes 20.

Hereinafter, the load port 100, the index module 200, the first buffer module 300, the coating and developing module 400, the second buffer module 500, the pre/post-exposure process module 600, and the interface module 700 will be described in detail.

The load port 100 includes mounting tables 120 on which the cassettes 20, each of which has the substrates W received therein, are placed. The mounting tables 120 are arranged in a row along the second direction 14. In FIG. 1, four mounting tables 120 are provided.

The index module 200 transfers the substrates W between the cassettes 20 placed on the mounting tables 120 of the load port 100 and the first buffer module 300. The index module 200 includes a frame 210, an index robot 220, and a guide rail 230. The frame 210 has a substantially rectangular parallelepiped shape with an empty space inside and is disposed between the load port 100 and the first buffer module 300. The frame 210 of the index module 200 may be located in a lower position than a frame 310 of the first buffer module 300 that will be described below. The index robot 220 and the guide rail 230 are disposed in the frame 210. The index robot 220 has a structure capable of 4-axis driving such that a hand 221 directly handling the substrates W is movable in the first direction 12, the second direction 14, and the third direction 16 and is rotatable. The index robot 220 includes the hand 221, an arm 222, a support rod 223, and a base 224. The hand 221 is fixedly attached to the arm 222. The arm 222 is provided in a retractable and rotatable structure. The support rod 223 is arranged such that the lengthwise direction thereof is parallel to the third direction 16. The arm 222 is coupled to the support rod 223 so as to be movable along the support rod 223. The support rod 223 is fixedly coupled to the base 224. The guide rail 230 is arranged such that the lengthwise direction thereof is parallel to the second direction 14. The base 224 is coupled to the guide rail 230 so as to be rectilinearly movable along the guide rail 230. Furthermore, although not illustrated, a door opener for opening/closing the doors of the cassettes 20 is additionally provided in the frame 210.

The first buffer module 300 includes the frame 310, a first buffer 320, a second buffer 330, a cooling chamber 350, and a first buffer robot 360. The frame 310 has a rectangular parallelepiped shape with an empty space inside and is disposed between the index module 200 and the coating and developing module 400. The first buffer 320, the second buffer 330, the cooling chamber 350, and the first buffer robot 360 are located in the frame 310. The cooling chamber 350, the second buffer 330, and the first buffer 320 are sequentially arranged along the third direction 16 from bottom to top. The first buffer 320 is located at the height corresponding to a coating module 401 of the coating and developing module 400 that will be described below, and the second buffer 330 and the cooling chamber 350 are located at the height corresponding to a developing module 402 of the coating and developing module 400 that will be described below. The first buffer robot 360 is located to be spaced a predetermined distance apart from the second buffer 330, the cooling chamber 350, and the first buffer 320 in the second direction 14.

Each of the first buffer 320 and the second buffer 330 temporarily stores a plurality of substrates W. The second buffer 330 includes a housing 331 and a plurality of supports 332. The supports 332 are disposed in the housing 331 and are spaced apart from each other along the third direction 16. One substrate W is placed on each of the supports 332. The housing 331 has openings (not illustrated) that face the directions in which the index robot 220, the first buffer robot 360, and a developer robot 482 are provided, respectively, such that the index robot 220, the first buffer robot 360, and the developer robot 482 of the developing module 402, which will be described below, load the substrates W onto the supports 332 in the housing 331 or unload the substrates W from the supports 332 in the housing 331. The first buffer 320 has a structure substantially similar to that of the second buffer 330. However, a housing 321 of the first buffer 320 has openings that face the directions in which the first buffer robot 360 and a coater robot 432 located in the coating module 401 are provided, respectively. The number of supports 332 provided in the first buffer 320 may be the same as, or different from, the number of supports 332 provided in the second buffer 330. According to an embodiment, the number of supports 332 provided in the second buffer 330 may be larger than the number of supports 322 provided in the first buffer 320.

The first buffer robot 360 transfers the substrates W between the first buffer 320 and the second buffer 330. The first buffer robot 360 includes a hand 361, an arm 362, and a support rod 363. The hand 361 is fixedly attached to the arm 362. The arm 362 has a retractable structure to enable the hand 361 to move along the second direction 14. The arm 362 is coupled to the support rod 363 so as to be rectilinearly movable along the support rod 363 in the third direction 16. The support rod 363 has a length extending from the position corresponding to the second buffer 330 to the position corresponding to the first buffer 320. The support rod 363 may further extend in the upper or lower direction. The first buffer robot 360 may be provided such that the hand 361 simply performs only 2-axis driving along the second direction 14 and the third direction 16.

The cooling chamber 350 cools the substrate W. The cooling chamber 350 includes a housing 351 and a cooling plate 352. The cooling plate 352 has an upper surface on which the substrate W is placed and a cooling unit 353 that cools the substrate W. Various methods, such as cooling by cooling water, cooling using a thermoelectric element, or the like, may be used for the cooling unit 353. Furthermore, the cooling chamber 350 may include a lift pin assembly (not illustrated) that locates the substrate W on the cooling plate 352. The housing 351 has openings (not illustrated) that face the directions in which the index robot 220 and the developer robot 482 are provided, respectively, such that the index robot 220 and the developer robot 482 provided in the developing module 402 load the substrate W onto the cooling plate 352 or unload the substrate W from the cooling plate 352. In addition, the cooling chamber 350 may include doors (not illustrated) that open or close the openings described above.

The coating and developing module 400 performs a process of coating the substrate W with photoresist before an exposing process and performs a developing process on the substrate W after the exposing process. The coating and developing module 400 has a substantially rectangular parallelepiped shape. The coating and developing module 400 includes a coating module 401 and a developing module 402. The coating module 401 and the developing module 402 may be disposed on different floors so as to be divided from each other. According to an embodiment, the coating module 401 is located over the developing module 402.

The coating module 401 performs a process of coating the substrate W with a light-sensitive material such as photoresist and performs a heat treatment process, such as heating or cooling, on the substrate W before and after the photoresist coating process. The coating module 401 includes photoresist coating chambers 410, bake units 420, and a transfer chamber 430. The photoresist coating chambers 410, the bake units 420, and the transfer chamber 430 are sequentially arranged along the second direction 14. Accordingly, the photoresist coating chambers 410 and the bake units 420 are spaced apart from each other in the second direction 14, with the transfer chamber 430 therebetween. The photoresist coating chambers 410 are arranged in the first direction 12 and the third direction 16. The drawings illustrate an example that six photoresist coating chambers 410 are provided. The bake units 420 are arranged in the first direction 12 and the third direction 16. The drawings illustrate an example that six bake units 420 are provided. However, a larger number of bake units 420 may be provided.

The transfer chamber 430 is located side by side with the first buffer 320 of the first buffer module 300 in the first direction 12. The coater robot 432 and a guide rail 433 are located in the transfer chamber 430. The transfer chamber 430 has a substantially rectangular shape. The coater robot 432 transfers the substrate W between the bake units 420, the photoresist coating chambers 400, the first buffer 320 of the first buffer module 300, and a first cooling chamber 520 of the second buffer module 500 that will be described below. The guide rail 433 is arranged such that the lengthwise direction thereof is parallel to the first direction 12. The guide rail 433 guides a rectilinear movement of the coater robot 432 in the first direction 12. The transfer robot 432 includes a hand 434, an arm 435, a support rod 436, and a base 437. The hand 434 is fixedly attached to the arm 435. The arm 435 has a retractable structure to enable the hand 434 to move in the horizontal direction. The support rod 436 is arranged such that the lengthwise direction thereof is parallel to the third direction 16. The arm 435 is coupled to the support rod 436 so as to be rectilinearly movable along the support rod 463 in the third direction 16. The support rod 436 is fixedly coupled to the base 437, and the base 437 is coupled to the guide rail 433 so as to be movable along the guide rail 433.

The photoresist coating chambers 410 all have the same structure. However, the types of photoresists used in the respective photoresist coating chambers 410 may differ from one another. For example, chemical amplification resist may be used as photoresist. Each of the photoresist coating chambers 410 coats the substrate W with photoresist. The photoresist coating chamber 410 includes a housing 411, a support plate 412, and a nozzle 413. The housing 411 has a cup shape with an open top. The support plate 412 is located in the housing 411 and supports the substrate W. The support plate 412 is provided so as to be rotatable. The nozzle 413 dispenses the photoresist onto the substrate W placed on the support plate 412. The nozzle 413 may have a circular tubular shape and may dispense the photoresist onto the center of the substrate W. Selectively, the nozzle 413 may have a length corresponding to the diameter of the substrate W, and a dispensing opening of the nozzle 413 may have a slit shape. Additionally, the photoresist coating chamber 410 may further include a nozzle 414 for dispensing a cleaning solution such as deionized water to clean the surface of the substrate W that is coated with the photoresist.

The bake units 420 may perform heat treatment on the substrate W. For example, the bake units 420 perform a prebake process of removing organics or moisture on the surface of the substrate W by heating the substrate W to a predetermined temperature before the substrate W is coated with the photoresist, or perform a soft bake process after the substrate W is coated with the photoresist. In addition, the bake units 420 perform a cooling process of cooling the substrate W after the heating processes.

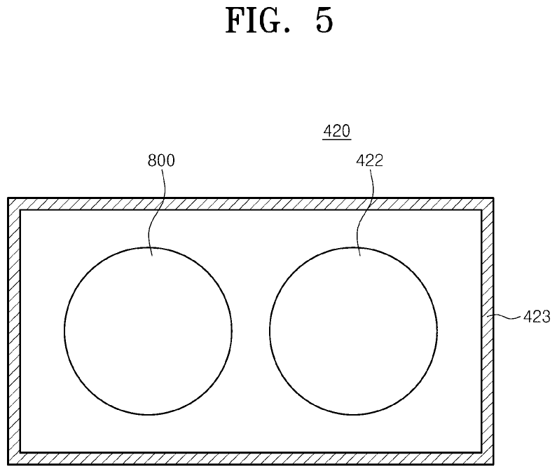

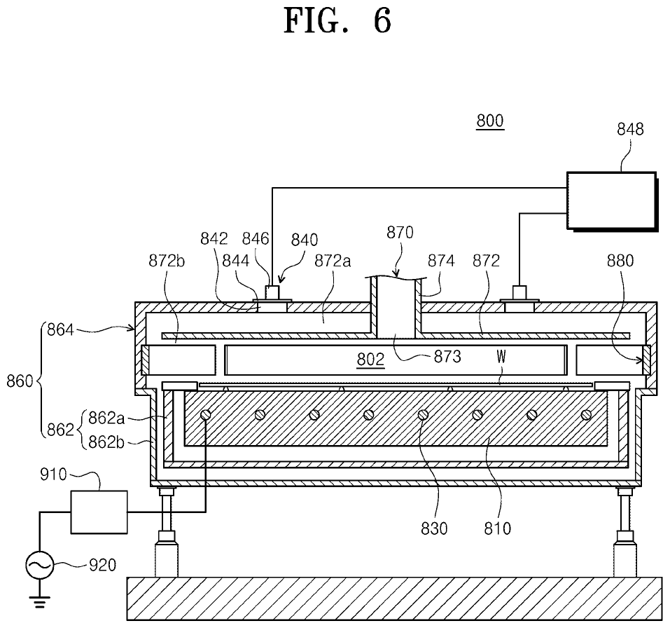

FIG. 5 is a plan view illustrating the bake unit according to an embodiment of the inventive concept. FIG. 6 is a sectional view illustrating a heating unit for performing a heating process in the bake unit of FIG. 5.

Referring to FIGS. 5 and 6, the bake unit 420 may include a process chamber 423, a cooling plate 422, and a heating unit 800.

The process chamber 423 has a heat treatment space therein. The process chamber 423 may have a rectangular parallelepiped shape. The cooling plate 422 may cool the substrate W heated by the heating unit 800. The cooling plate 422 may be located in the heat treatment space. The cooling plate 422 may have a circular plate shape. A cooling means, such as cooling water or a thermoelectric element, is provided in the cooling plate 422. For example, the cooling plate 422 may cool the heated substrate W to room temperature.

The heating unit 800 heats the substrate W. The heating unit 800 may include a housing 860, a heating plate 810, a heating member 830, an external gas supply unit 840, a heater 880, and an exhaust member 870.

The housing 860 has a process space 802 in which a heating process is performed on the substrate W. The housing 860 includes a lower body 862, an upper body 864, and an actuator (not illustrated).

The lower body 862 may have a container shape that is open at the top. The heating plate 810 and the heating member 830 are located in the lower body 862. The lower body 862 includes double heat-insulating covers 862a and 862b to prevent thermal deformation of apparatuses around the heating plate 810. The double heat-insulating covers 862a and 862b minimize the exposure of the apparatuses around the heating plate 810 to high-temperature heat generated from the heating member 830. The double heat-insulating covers 862a and 862b include the primary heat-insulating cover 862a and the secondary heat-insulating cover 862b. The primary heat-insulating cover 862a and the secondary heat-insulating cover 862b are spaced apart from each other.

The upper body 864 has a container shape that is open at the bottom. The upper body 864 is combined with the lower body 862 to form the process space 802 inside. The upper body 864 has a larger diameter than the lower body 862. The upper body 864 is located over the lower body 862. The upper body 864 is able to be moved in the vertical direction by the actuator. The upper body 864 is able to be vertically moved between a raised position and a lowered position. Here, the raised position is a position where the upper body 864 is separated from the lower body 862, and the lowered position is a position where the upper body 864 is brought into contact with the lower body 862. In the lowered position, the gap between the upper body 864 and the lower body 862 is blocked. Accordingly, when the upper body 864 is moved to the lowered position, the process space 802 is formed by the upper body 864, the lower body 862, and the heating plate 810.

Although not illustrated, sealing members for preventing introduction of outside air into the process space 802 may be included in the housing 860. For example, the sealing members may seal the gap between the lower body 862 and the upper body 864.

The heating plate 810 is located in the process space 802. The heating plate 810 is located on one side of the cooling plate 422. The heating plate 810 has a circular plate shape. The upper surface of the heating plate 810 serves as a support area on which the substrate W is placed. The heating plate 810 has a plurality of pin holes 812 formed on the upper surface thereof. For example, three pin holes 812 may be formed on the upper surface of the heating plate 810. The pin holes 812 are located to be spaced apart from each other along the circumferential direction of the heating plate 810. The pin holes 812 are located to be spaced apart from each other at constant intervals. Lift pins (not illustrated) are provided in the pin holes 812, respectively. The lift pins are able to be moved in the vertical direction by a drive member (not illustrated).

The heating member 830 heats the substrate W placed on the heating plate 810 to a preset temperature. A plurality of heating members 830 may be provided in different regions of the heating plate 810 to perform heat treatment on the substrate W for each of the regions.

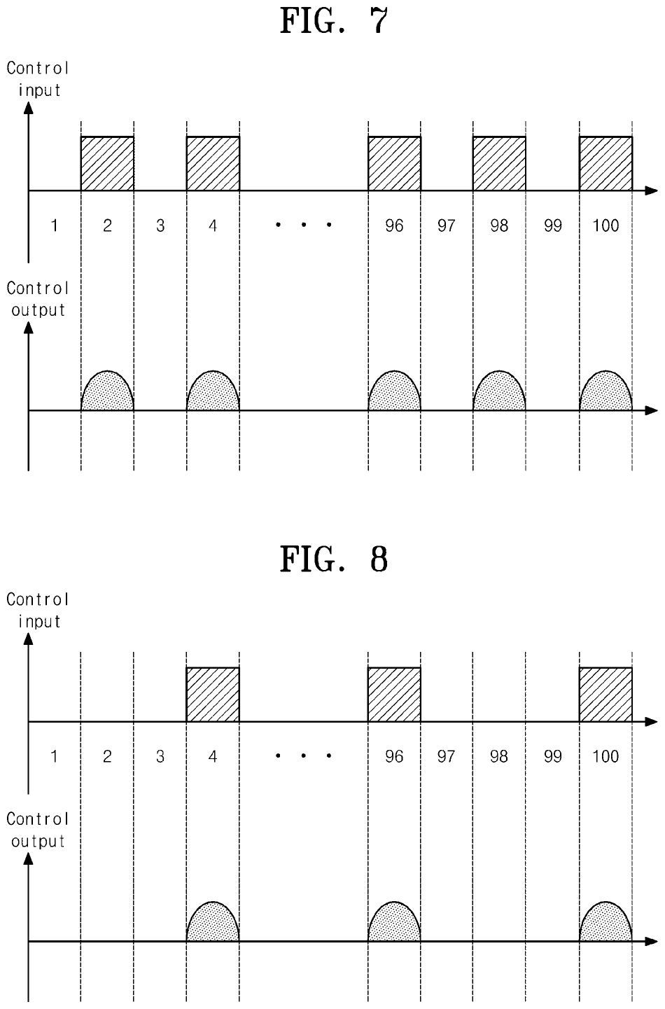

A power supply 920 supplies power to the heating member 830. The power supply 920 may be an alternating current (AC) power supply that supplies AC power. A controller 910 controls the heating member 830 using AC power output from the power supply 920. The controller 910 may control the heating temperature of the substrate W by alternately turning on and off a control input for controlling the heating member 830. Furthermore, the controller 910 may determine the turn-on time of the control input to the heating member 830, based on the frequency of the AC power. Hereinafter, a method of controlling, by the controller 910, the heating member 830 using AC power output from the power supply 920 will be described in detail with reference to FIGS. 7 and 8.

FIGS. 7 and 8 are views illustrating waveforms of control inputs and control outputs according to an embodiment of the inventive concept.

Referring to FIGS. 7 and 8, the controller 910 alternately turns on and off a control input to the heating member 830. A control output is generated when the control input is turned on. Accordingly, the control output may also be alternately turned on and off, thereby preventing the occurrence of temperature vibration in the heating member 830. However, because the control output is generated when the control input is turned on for more than the time period of one pulse, the controller 910 may determine the turn-on time, based on the frequency of AC power output from the power supply 920.

The controller 910 may determine the turn-on timing of the control input, which is a time point at which the control input is turned on, depending on the output ratio of the AC power and the unit pulse time of the AC power. Here, the output ratio of the AC power may be a preset value or a value randomly set by a user. Furthermore, the unit pulse time of the AC power may be calculated based on the frequency of the AC power. Specifically, the unit pulse time may be a value obtained by dividing the reciprocal of the frequency of the AC power by 2.

The controller 910 may calculate the unit output of the AC power using the output ratio of the AC power and the unit pulse time of the AC power, and when the sum of the unit outputs is greater than or equal to the unit pulse time, the controller 910 may determine the corresponding time point to be the turn-on timing of the control input. Specifically, the unit output may be a value obtained by multiplying the output ratio of the AC power and the unit pulse time of the AC power together. For example, when the frequency of the AC power is 50 Hz and the output ratio of the AC power is 50%, the unit pulse time may be 1/100 that is obtained by dividing 1/50 by 2, and the unit output may be 0.5/100 that is obtained by multiplying the output ratio of the AC power and the unit pulse time of the AC power. In this case, the sum of the unit outputs in the second unit pulse may be 0.5/100 +0.5/100 =1/100 and may be greater than or equal to the unit pulse time. Accordingly, the corresponding time point may be determined to be the turn-on timing of the control input. In another example, when the frequency of the AC power is 50 Hz and the output ratio thereof is 25%, the unit pulse time may be 1/100, and the unit output may be 0.25/100. In this case, the sum of the unit outputs in the fourth unit pulse may be 0.25/100 +0.25/100 +0.25/100 +0.25/100 =1/100, and as illustrated in FIG. 8, may be greater than or equal to the unit pulse time. Accordingly, the corresponding time point may be determined to be the turn-on timing of the control input. Furthermore, the controller 910 may determine the turn-on timing of the control input in consideration of sampling time. The sampling time may be a preset value or a value set by the user. The controller 910 may calculate the unit output, by multiplying the product of the output ratio of the AC power and the unit pulse time of the AC power by the sampling time.

The controller 910 may repeatedly perform the process of determining the turn-on timing of the control input. For example, when the frequency of the AC power is 50 Hz and the output ratio of the AC power is 50%, the sum of the unit outputs in the second unit pulse may be equal to 1/100, and the controller 910 may determine the corresponding time point to be the turn-on timing of the control input. Thereafter, the controller 910 may subtract the unit outputs from the sum of the unit outputs and may calculate the sum of the unit outputs again, and when the sum of the unit outputs in the fourth unit pulse is equal to 1/100, the controller 910 may determine the corresponding time point to be the turn-on timing of the control input. The process may be repeatedly performed for all the unit outputs (the reciprocal of the unit pulse time).According to the embodiment of the inventive concept, the controller 910 may alternately turn on and off the control input, thereby preventing the occurrence of temperature vibration and improving temperature control performance. In addition, the controller 910 may accurately determine the turn-on timing of the control input in consideration of the frequency of the AC power and the output ratio of the AC power, thereby improving the accuracy of temperature control.

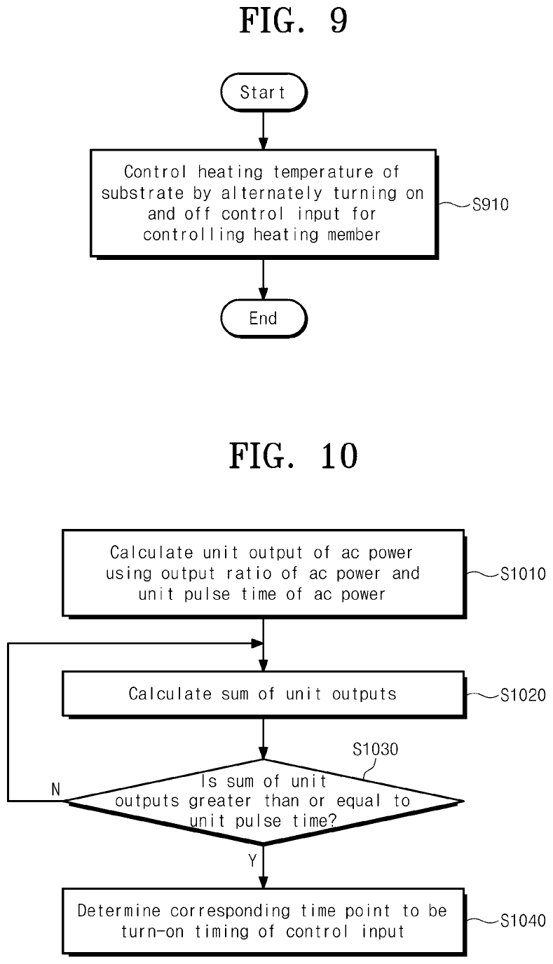

FIGS. 9 and 10 are flowcharts illustrating a substrate treating method according to an embodiment of the inventive concept.

The controller 910 controls the heating temperature of a substrate by alternately turning on and off a control input for controlling the heating member 830 (S910). Specifically, the controller 910 may calculate the unit output of AC power using the output ratio of the AC power and the unit pulse time of the AC power (S1010) and may calculate the sum of the calculated unit outputs (S1020), and when the sum of the unit outputs is greater than or equal to the unit pulse time (S1030: Y), the controller 910 may determine the corresponding time point to be the turn-on timing of the control input (S1040). When the sum of the unit outputs is less than the unit pulse time (S1030: N), the controller 910 may repeatedly perform the process of calculating the sum of the unit outputs until the sum of the unit outputs is greater than or equal to the unit pulse time.

Furthermore, steps S1020 to S1040 may be repeatedly performed. Accordingly, when controlling the heating temperature of the substrate by alternately turning on and off the control input, the controller 910 may calculate the accurate turn-on timing of the control input, thereby improving the accuracy of the substrate temperature control.

The substrate treating method may be implemented as a program that can be executed by a computer. The substrate treating method may be executed in an application form and may be stored in a computer readable recoding medium.

The computer readable recording medium may be, but is not limited to, a volatile memory such as a static RAM (SRAM), a dynamic RAM (DRAM) or a synchronous DRAM (SDRAM), a non-volatile memory such as a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM) or a ferroelectric RAM (FRAM), a floppy disk, a hard disk, or an optically readable medium (e.g., a storage medium such as a CD-ROM, a DVD, or the like).

As described above, according to the various embodiments of the inventive concept, the control input for controlling the heating member is alternately turned on and off, thereby preventing temperature vibration in the heater and improving the temperature control performance of the heater.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. The scope of the inventive concept should be determined by the technical idea of the claims, and it should be understood that the scope of the inventive concept is not limited to the literal description of the claims, but actually extends to the category of equivalents of technical value.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. An apparatus for treating a substrate, the apparatus comprising:
a housing having a process space therein;
a plate configured to support the substrate in the housing;
a heating member provided in the plate and configured to heat the substrate;
a power supply configured to supply AC power to the heating member; and
a controller configured to control the heating member using the AC power output from the power supply, wherein the controller controls heating temperature of the substrate by alternately turning on and off a control input for controlling the heating member.

2. The apparatus of claim 1, wherein the controller determines turn-on time of the control input supplied to the heating member, based on a frequency of the AC power.

3. The apparatus of claim 2, wherein the controller determines turn-on timing of the control input depending on an output ratio of the AC power and unit pulse time of the AC power.

4. The apparatus of claim 3, wherein the controller calculates the unit pulse time of the AC power, based on the frequency of the AC power.

5. The apparatus of claim 3, wherein the controller calculates a unit output of the AC power using the output ratio of the AC power and the unit pulse time of the AC power, and when the sum of the unit outputs is greater than or equal to the unit pulse time, the controller determines a corresponding time point to be the turn-on timing of the control input.

6. The apparatus of claim 5, wherein the controller repeatedly performs the process of determining the turn-on timing of the control input.

7. The apparatus of claim 3, wherein the controller determines the turn-on timing of the control input in consideration of sampling time.

8. A bake apparatus comprising:
a housing having a process space therein;
a plate configured to support a substrate in the housing;
a heating member provided in the plate and configured to heat the substrate;
a power supply configured to supply AC power to the heating member; and
a controller configured to control the heating member using the AC power output from the power supply, wherein the controller controls heating temperature of the substrate by alternately turning on and off a control input for controlling the heating member and determining turn-on timing of the control input depending on an output ratio of the AC power and unit pulse time of the AC power.

9. The bake apparatus of claim 8, wherein the controller calculates the unit pulse time of the AC power, based on a frequency of the AC power.

10. The bake apparatus of claim 9, wherein the controller calculates a unit output of the AC power using the output ratio of the AC power and the unit pulse time of the AC power, and when the sum of the unit outputs is greater than or equal to the unit pulse time, the controller determines a corresponding time point to be the turn-on timing of the control input.

11. The bake apparatus of claim 10, wherein the controller repeatedly performs the process of determining the turn-on timing.

12. The bake apparatus of claim 8, wherein the controller determines the turn-on timing of the control input in consideration of sampling time.

13. A method for treating a substrate by controlling a heating member provided in a plate for supporting the substrate in a chamber, the method comprising:
controlling heating temperature of the substrate by alternately turning on and off a control input for controlling the heating member.

14. The method of claim 13, wherein AC power is supplied to the heating member, and
wherein turn-on time of the control input is determined based on a frequency of the AC power.

15. The method of claim 14, wherein turn-on timing of the control input is determined depending on an output ratio of the AC power and unit pulse time of the AC power.

16. The method of claim 15, wherein the unit pulse time of the AC power is calculated based on the frequency of the AC power.

17. The method of claim 15, wherein a unit output of the AC power is calculated by using the output ratio of the AC power and the unit pulse time of the AC power, and when the sum of the unit outputs is greater than or equal to the unit pulse time, a corresponding time point is determined to be the turn-on timing of the control input.

18. The method of claim 17, wherein the process of determining the turn-on timing of the control input is repeatedly performed.

19. The method of claim 15, wherein the turn-on timing of the control input is determined in consideration of sampling time.
